(19) United States
(12) Patent Application Publication
(10) Pub. No.: US 2013/0008479 A1
(43) Pub. Date: Jan. 10, 2013

(54) THERMOELECTRIC ELEMENT DESIGN

(76) Inventor: Peng Chen, Painted Post, NY (US)

(21) Appl. No.: 13/177,616

(22) Filed: Jul. 7, 2011

(51) Int. Cl. H01L 35/32

(52) U.S. Cl. 136/205

(57) ABSTRACT

Thermoelectric elements having a non-uniform effective thermal conductivity include opposing contact surfaces for making electrical and thermal contact with respective hot side and cold side electrical interconnects. The contact surfaces having corresponding contact areas that are each greater than an intermediate cross-sectional area of the thermoelectric elements.

### BACKGROUND

The present disclosure relates generally to thermoelectric elements and thermoelectric devices comprising such elements, and more particularly to thermoelectric elements having a non-uniform cross-sectional area.

The thermoelectric effect involves the conversion of thermal energy into electrical energy. Notably, a thermoelectric device such as a thermoelectric power generator can be used to produce electrical energy from a gradient in temperature, and advantageously can operate using waste heat such as industrial waste heat generated in chemical reactors, incineration plants, iron and steel melting furnaces, and in automotive exhaust. Efficient thermoelectric devices can recover about 20% or more of the heat energy released by such industrial systems, though due to the “green nature” of the energy, lower efficiencies are also of interest. Compared to other power generators, thermoelectric power generators operate without toxic gas emission, and with longer lifetimes and lower operating and maintenance costs.

The conversion of thermal energy into electrical energy is based on the Seebeck effect, whereby, given a material exposed to a temperature gradient, an electrical potential will develop that is proportional to both the temperature difference and the Seebeck coefficients of the material.

The Seebeck coefficient, also referred to as the thermopower or thermoelectric power of a material, is a measure of the magnitude of an induced thermoelectric voltage in response to a temperature difference across that material. The Seebeck coefficient, α, is defined as the thermoelectric voltage that develops across a material in response to a temperature gradient,

$$α = \frac{Δ V}{∇ T}$$

and has units of VK⁻¹, though typical values are in the range of microvolts per Kelvin.

A thermoelectric device typically includes two types of semiconducting material (e.g., n-type and p-type) though thermoelectric devices comprising a single thermoelectric material (either n-type or p-type) are also known. Conventionally, both n-type and p-type conductors are used to form n-type and p-type elements within a device. In a typical device, alternating n-type and p-type elements are electrically connected in series and thermally connected in parallel between electrically insulating but thermally conducting plates. Because the equilibrium concentration of carriers in a semiconductor is a function of temperature, if a temperature gradient is placed across a device with n-type and p-type elements, the carrier concentrations in both elements will differ. The resulting motion of charge carriers will create an electric current.

For purely p-type materials that have only positive mobile charge carriers (holes), α>0. For purely n-type materials that have only negative mobile charge carriers (electrons), α<0. In practice, materials often have both positive and negative charge carriers, and the sign of a usually depends on which carrier type predominates.

The maximum efficiency of a thermoelectric material depends on the amount of heat energy provided and on materials properties such as the Seebeck coefficient, electrical resistivity and thermal conductivity. A figure of merit, ZT, can be used to evaluate the quality of thermoelectric materials. ZT is a dimensionless quantity that for small temperature differences is defined by ZT=σα²T/κ, where σ is the electric conductivity, α is the Seebeck coefficient, T is temperature, and κ is the thermal conductivity of the material. Another indicator of thermoelectric material quality is the power factor, PF=σα².

A material with a large figure of merit will usually have a large Seebeck coefficient (found in low carrier concentration semiconductors or insulators) and a large electrical conductivity (found in high carrier concentration metals). Further, a good thermoelectric material advantageously has a low thermal conductivity.

Thermoelectric materials advantageously have high electrical conductivity, high Seebeck coefficient, and low thermal conductivity. These properties can be difficult to optimize simultaneously, however, and an improvement in one often comes at the detriment of another. For instance, most insulators, which have low electron densities, have a high Seebeck coefficient but a low electrical conductivity.

Good thermoelectric materials are typically heavily-doped semiconductors or semimetals with a carrier concentration of 10¹⁹ to 10²¹ carriers/cm³. To ensure that the net Seebeck effect is large, there should only be a single type of carrier. Mixed n-type and p-type conduction will lead to opposing Seebeck effects and lower thermoelectric efficiency. In materials having a sufficiently large band gap, n-type and p-type carriers can be separated, and doping can be used to produce a dominant carrier type. Thus, good thermoelectric materials typically have band gaps large enough to have a large Seebeck coefficient, but small enough to have a sufficiently high electrical conductivity.

Thermal conductivity in such materials comes from two sources. Phonons traveling through the crystal lattice transport heat and contribute to lattice thermal conductivity, and electrons (or holes) transport heat and contribute to electronic thermal conductivity.

One approach to enhancing ZT is to minimize the lattice thermal conductivity. This can be done by increasing phonon scattering, for example, by introducing heavy atoms, disorder, large unit cells, clusters, rattling atoms, grain boundaries and interfaces.

Previously-commercialized thermoelectric materials include bismuth telluride-based and (Si, Ge)-based materials. The family of (Bi,Pb)₂(Te,Se,S)₃ materials, for example, has a figure of merit in the range of 1.0-1.2. Slightly higher values can be achieved by selective doping, and still higher values can be reached for quantum-confined structures. However, due to their chemical stability and melting point, the application of these materials is limited to relatively low temperatures (<450° C.), and even at such relatively low temperatures, they require protective surface coatings. Other known classes of thermoelectric materials such as clathrates, skutterudites and silicides also have limited applicability to elevated temperature operation. The composition of the thermoelectric elements disclosed herein can be substantially homogeneous.

FIG. 1 shows a cross-sectional view of a portion of an example thermoelectric module 100. The module 100 has a planar design comprising a plurality of n-type and p-type thermoelectric elements 122, 124 connected electrically in series via electrical interconnects 130, 140. Typical thermoelectric elements in such a design are shaped as rectangular or square prisms. The thermoelectric elements 122, 124 and the respective interconnects 130, 140 are mounted between opposing thermally-conducting ceramic substrates 135, 145. The ceramic substrates 135, 145 provide mechanical support and electrical insulation. To form a thermoelectric device, the foregoing assembly is sandwiched between a heat source 137 and a heat sink 147.

When the module is exposed to a heat source 137 and a heat sink 147, the temperature gradient across the couple induces current flow around the circuit (shown by arrows). For a material having a ZT value of about 1.5, the conversion efficiency is about 10% for a temperature gradient of about 200K (i.e., Tₕₒₜ=500K and T_{cold}=300K) and about 20% for a temperature gradient of about 550K (i.e., Tₕₒₜ=850K and T_{cold}=300K).

FIG. 2 shows an example thermoelectric module 200 having a cylindrical design. The cylindrical thermoelectric module comprises a plurality of radially-extending n-type and p-type thermoelectric elements 222, 224 that are electrically connected via circumferentially oriented electrical interconnects 230, 240. The individual thermoelectric elements are shaped as prismatic wedges. The thermoelectric elements and interconnects are sandwiched between coaxial pipes 235, 245 typically made from electrically insulating and thermally conducting ceramic. A heat source and a heat sink can be provided within the inner core 237 of the inner coaxial pipe 235 and in a region 247 external to the outer coaxial pipe 245. In an alternate configuration, the location of the heat source and the heat sink can be interchanged.

FIG. 3 shows an example thermoelectric module 300 having an alternate cylindrical design. The thermoelectric module 300 comprises disc-shaped (ring-shaped) n-type and p-type thermoelectric elements 322, 324 that are alternately stacked in an axial, cylindrical configuration. The thermoelectric elements are electrically connected via circumferentially oriented electrical interconnects 330, 340 (e.g., bands). The thermoelectric elements and interconnects are sandwiched between coaxial pipes 335, 345, which can be made from electrically insulating and thermally conducting ceramic. A heat source and a heat sink can be provided within the inner core of the inner coaxial pipe and external to the outer coaxial pipe, respectively. As with the previous design, the location of the heat source and the heat sink can be interchanged.

Example thermoelectric device designs are disclosed in U.S. Pat. Nos. 6,020,671 and 4,056,406, the entire contents of which are incorporated herein by reference.

In certain device designs it can be advantageous to minimize the distance between the heat source and heat sink. Such a configuration uses shorter elements and therefore can use less thermoelectric material, thus lowering material costs. On the other hand, a more compact design can expose the entire module, including the thermoelectric elements, to higher thermal stresses that result from a higher temperature gradient. Moreover, by decreasing the distance between the heat source and the heat sink by merely shortening the length of the thermoelectric elements, the total thermal resistance between the heat source and heat sink is decreased, which counteracts the ability to maintain a high temperature gradient. The absence of a high temperature gradient is detrimental to realizing a high heat-to-electricity conversion efficiency.

While it may be possible to use thermoelectric elements having a uniformly-reduced cross-sectional area to achieve a higher thermal resistance and maintain a higher temperature gradient, the reduced cross-sectional area will disadvantageously increase the contact resistance between the elements and the interconnects.

In view of the foregoing, it would be advantageous to develop a thermoelectric device having a high thermoelectric figure of merit. More specifically, it would be advantageous to develop an energy efficient device architecture having a small footprint and high power output, which is compatible with elevated temperature operation and particularly with a high temperature gradient between hot and cold sides of the device.

### SUMMARY

These and other aspects and advantages of the invention can be achieved by a thermoelectric element comprising a first end comprising a first contact surface and having a first cross-sectional area, a second end comprising a second contact surface and having a second cross-sectional area, and an intermediate region between the first end and the second end having an intermediate cross-sectional area where the intermediate cross-sectional area is less than both the first cross-sectional area and the second cross-sectional area.

Additional features and advantages of the disclosure will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description present embodiments, and are intended to provide an overview or framework for understanding the nature and character of the invention as it is claimed. The accompanying drawings are included to provide a further understanding, and are incorporated into and constitute a part of this specification. The drawings illustrate various embodiments and together with the description serve to explain the principles and operations of the invention.

### BRIEF DESCRIPTION OF DRAWINGS

FIG. 1 is cross-sectional view of a portion of a thermoelectric module having a planar design;

FIG. 2 is cross-sectional view of a portion of a thermoelectric module having a cylindrical design;

FIG. 3 is cross-sectional view of a portion of an alternate thermoelectric module having a cylindrical design;

FIG. 4 is an example design of a thermoelectric generator;

FIG. 5 depicts an example array of thermoelectric elements according to one embodiment;

FIG. 6 depicts an example array of thermoelectric elements according to a further embodiment;

FIG. 7 shows an example thermoelectric element according to one embodiment;

FIG. 8 is cross-sectional view of a portion of a thermoelectric module comprising a plurality of the thermoelectric elements depicted in FIG. 7;

FIG. 9 is a cross-sectional view of a portion of a thermoelectric module comprising thermoelectric elements that include a voided region;

FIG. 10 is cross-sectional view of a portion of a thermoelectric module comprising thermoelectric elements having a dual “I” shape;

FIG. 11 is cross-sectional view of a portion of a cylindrical thermoelectric module comprising wedge-shaped thermoelectric modules each having a voided region;

FIG. 12 is cross-sectional view of a portion of a cylindrical thermoelectric module comprising disc-shaped thermoelectric modules each having a plurality of voided regions;

FIG. 13 is a plot of power per plate area, power density and efficiency for a thermoelectric couple comprising inventive and comparative thermoelectric elements for an electrical contact resistance of 4.6×10⁻⁸ ohm-m²; and

FIG. 14 is a plot of power per plate area, power density and efficiency for a thermoelectric couple comprising inventive and comparative thermoelectric elements for an electrical contact resistance of 6.9×10⁻⁹ ohm-m².

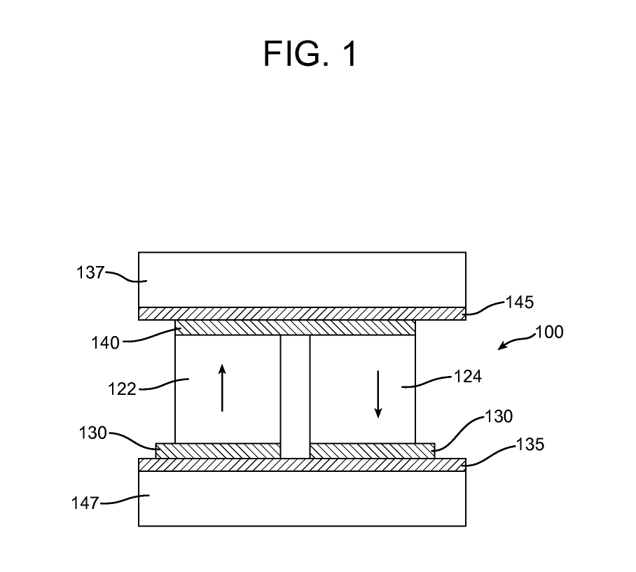

### DETAILED DESCRIPTION

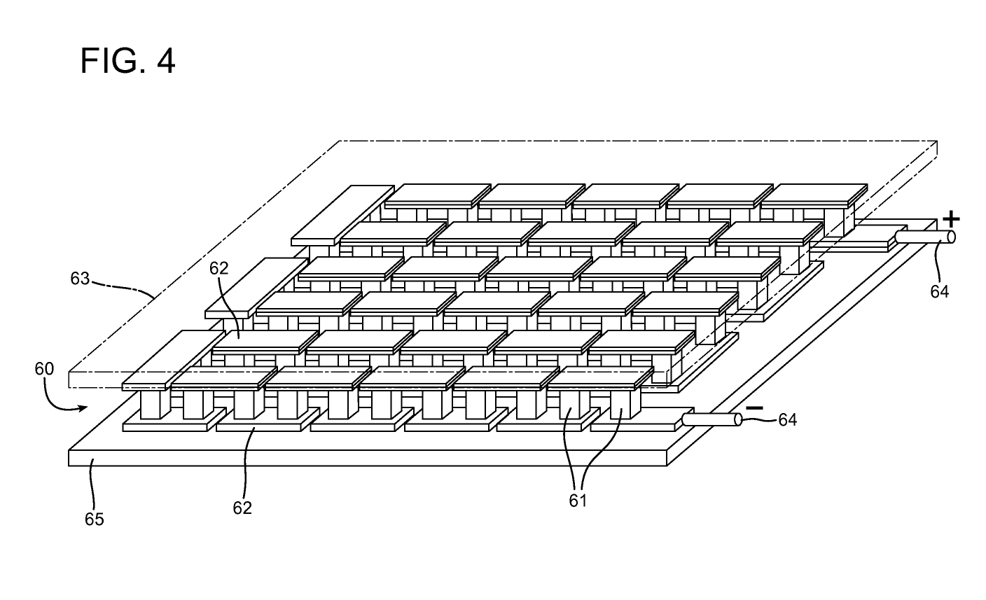

Various shapes and arrangements of thermoelectric elements have been proposed for integrating thermoelectric (TE) materials and components into a thermoelectric module. An example thermoelectric generator is illustrated in FIG. 4 where TE module 60 is shown formed between plates 63 and 65, respectively located on a hot side and a cold side of the module 60. In operation, heat is absorbed from the hot side through the top surface of plate 63 and rejected through the cold side at the bottom surface of plate 65. Plates 63 and 65 thereby act respectively as the heat source and heat sink for the module 60. Alternating p-type and n-type elements 61 are interconnected in series by metal interconnects 62 on both the hot and cold sides of the module 60. The total voltage of the module 60 can be obtained across end leads 64.

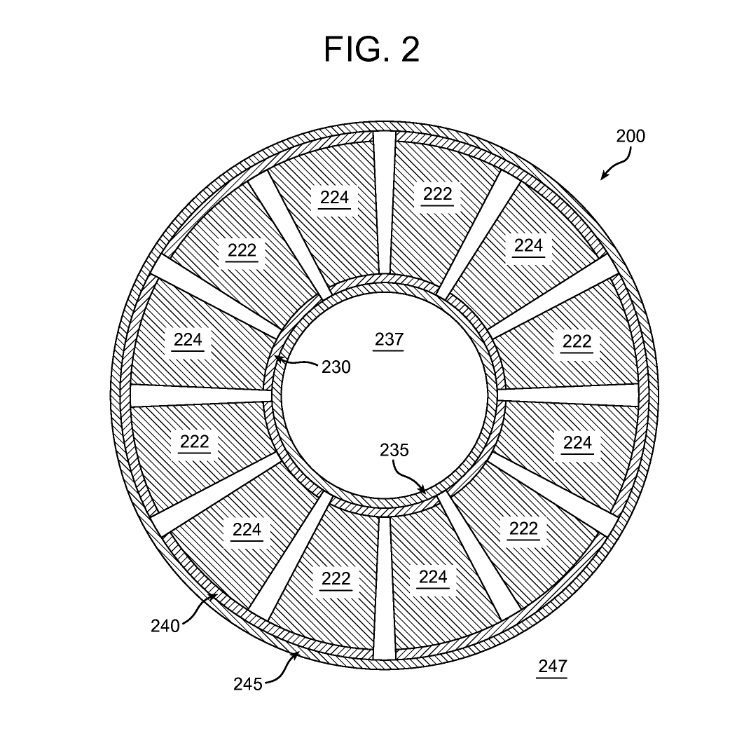

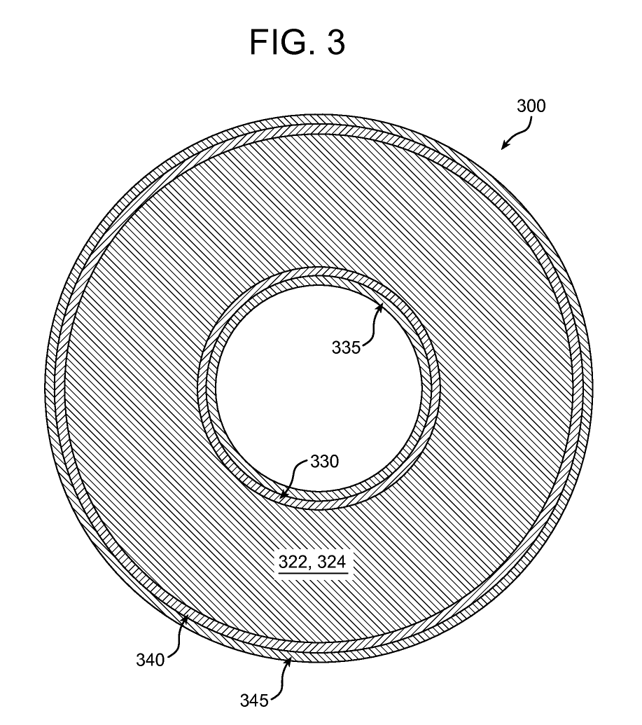

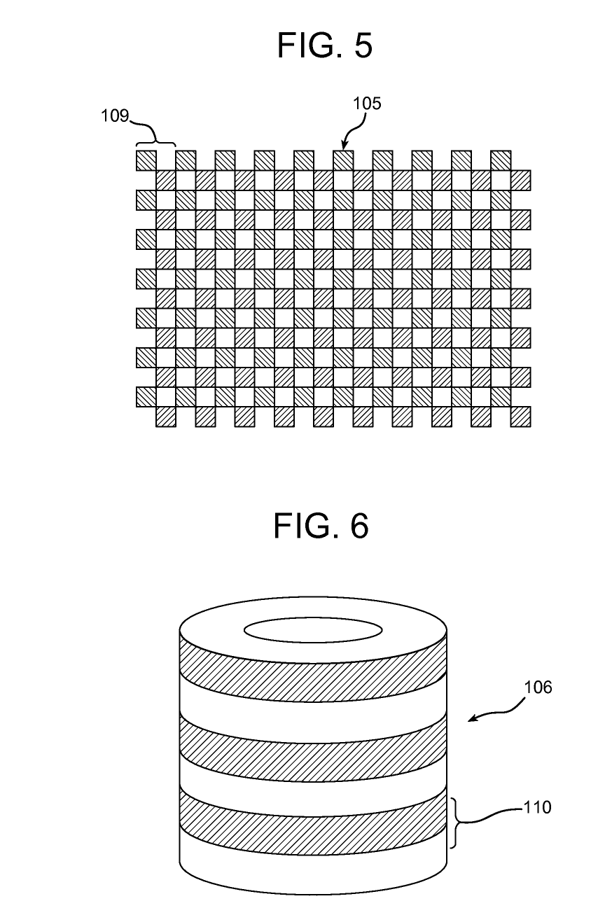

As shown in FIGS. 5 and 6, a thermoelectric generator may comprise different patterns of thermoelectric elements including, for example, a checkerboard pattern 105 with alternating n-type and p-type legs 109 (FIG. 5), an alternating stack 106 of n-type and p-type disks 110 (FIG. 6), radially-extending n-type and p-type fins (FIG. 2), or combinations thereof. Those of ordinary skill in the art would understand that various patterns of TE generation elements can be used without departing from the present disclosure or claims.

In embodiments, the n-type elements and p-type elements are physically separated from each other. Suitable separating layers may be made, for example, from a low thermal conductivity, low electrical conductivity material, such as, for example, a ceramic or glass-ceramic foam, coating or interlayer. The separating layer may be air.

According to embodiments of the disclosure, the p-type and n-type elements incorporated into a thermoelectric module have a non-uniform cross-section (i.e., variable cross-sectional area) such that a cross-sectional area at a location intermediate between the hot-side and cold-side ends of the element is less than the respective cross-sectional areas at the ends. By forming the thermoelectric elements with an intermediate region having a decreased cross-sectional area, the effective thermal resistance of the overall element can be increased such that a high temperature gradient can be sustained across the element without decreasing the contact area, which would increase the contact resistance. Thermoelectric generators that incorporate elements having the disclosed geometry can achieve a higher electric power output than generators comprising conventional elements and thus enable a more compact generator design, which can be beneficial in a number of applications including automotive applications where space can be limited.

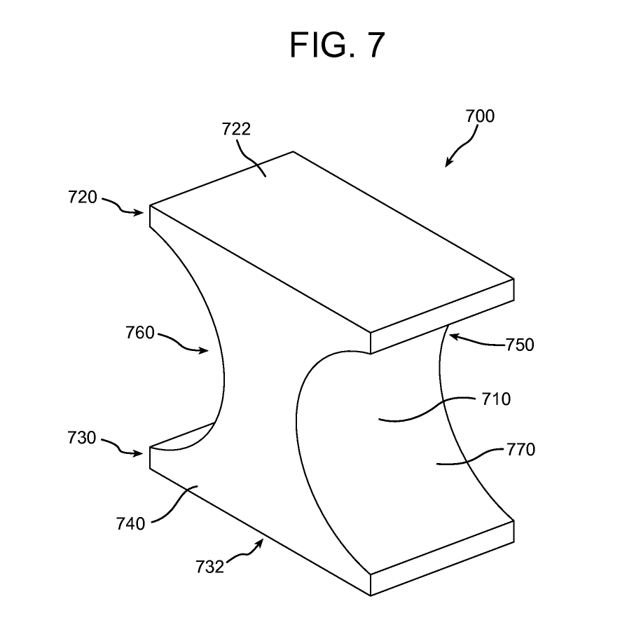

An example thermoelectric element having a non-uniform cross-sectional area is illustrated in FIG. 7. The thermoelectric element is formed from a thermoelectric material. The thermoelectric element 700 comprises a body 710 having opposing ends 720, 730 each having a respective contact surface 722, 732. Contact surface 722 is configured to make electrical and thermal contact with, for example, a hot side interconnect, and contact surface 732 is configured to make electrical and thermal contact with a cold side interconnect. Contact surface 722 has a hot-side contact area and contact surface 732 has a cold-side contact area. In embodiments, the hot-side contact area can be less than, equal to, or greater than the cold-side contact area.

The relatively large areas of the contact surfaces 722, 732 minimize the total contact resistance at the element-interconnect interface, while the relatively small intermediate cross-sectional area can increase the effective thermal resistance of the element, which enables operation of the element and its attendant module at a higher temperature gradient than devices comprising conventional elements. A higher thermoelectric conversion efficiency can result from the higher temperature gradient.

In embodiments, each end of the thermoelectric element has a corresponding cross-sectional area that may be equal to the corresponding contact area. In embodiments, however, the actual hot-side contact area may be greater than or less than a cross-sectional area of the thermoelectric element at the hot side, and the actual cold side contact area may be greater than or less than a cross-sectional area of the thermoelectric element at the cold side. Thus, contact surfaces 722, 732 can independently comprise planar or non-planar surfaces.

In the FIG. 7 embodiment, in addition to the opposing contact surfaces, which may optionally be co-planar, thermoelectric element 700 comprises one pair of parallel opposing sides 740, 750 and one pair of non-parallel, concave opposing sides 760, 770. In an alternative, non-illustrated embodiment, a thermoelectric element can be shaped like an hour-glass and comprise, for example, a continuous, non-planar concave side.

In an embodiment, the hot-side cross-sectional area lies in a first plane, the cold-side cross-sectional area lies in a second plane, and the intermediate cross-sectional area lies in a third plane such that first, second and third planes are co-planar.

FIG. 8 shows an example thermoelectric module comprising a plurality of thermoelectric elements 700 having an intermediate cross-sectional area that is less that the cross-sectional area at the contact end of the element. The thermoelectric elements depicted in FIGS. 7 and 8 have an “I” shaped cross-section.

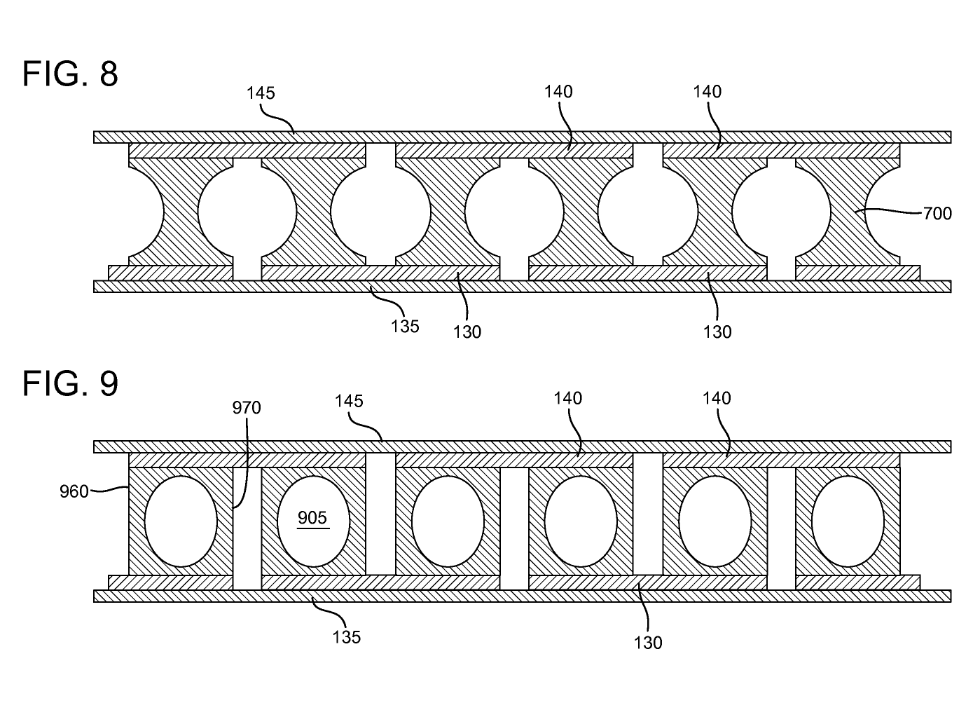

A thermoelectric element according to a further embodiment is illustrated in FIG. 9, which shows substantially rectangular thermoelectric elements comprising an interior void 905 such that an intermediate cross-sectional area that is less that the cross-sectional area at each contact end of the elements. In the embodiment shown in FIG. 9, side surfaces 960 and 970 may or may not be parallel. A void, if provided, may comprise a circular, oval or alternatively-shaped bore that passed partially though or completely through a cross-section of the element.

A void, if provided, can optionally be filled with a gas (e.g., inert gas) or other low thermal conductivity (e.g., solid) material. A void can be filled with air. A void can be evacuated so that a pressure within the void is less than atmospheric pressure.

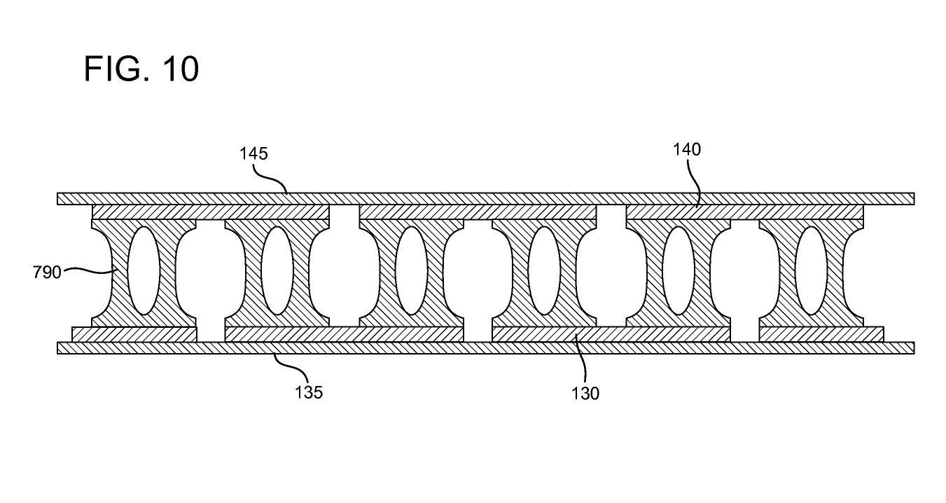

A thermoelectric element according to a yet further embodiment is illustrated in FIG. 10, which shows a plurality of elements 790 incorporated into an example module where the individual elements have a “double-I” shape.

An example thermoelectric element can have an overall length of 1 to 20 mm (e.g., 1, 2, 5, 10 or 20 mm), where the length is defined as the distance between opposing contact surfaces, and areal dimensions at the respective hot and cold ends of 1×1 mm² to 20×20 mm². In embodiments, the thickness and width of a thermoelectric element at the hot and cold ends can independently range from 1 to 20 mm (e.g., 1, 2, 5, 10 or 20 mm).

In embodiments, one or both of the thickness and the width of the thermoelectric element is less at an intermediate region between the hot and cold ends than at the hot and cold ends. In further embodiments, an intermediate area is from 10 to 99% of an area at the contact ends. Thus, the cross-sectional area displays a minimum between the hot and cold contact ends of the element. The minimum may be located equidistant from the hot and cold ends or, alternatively, the minimum may be located closer to one end than another.

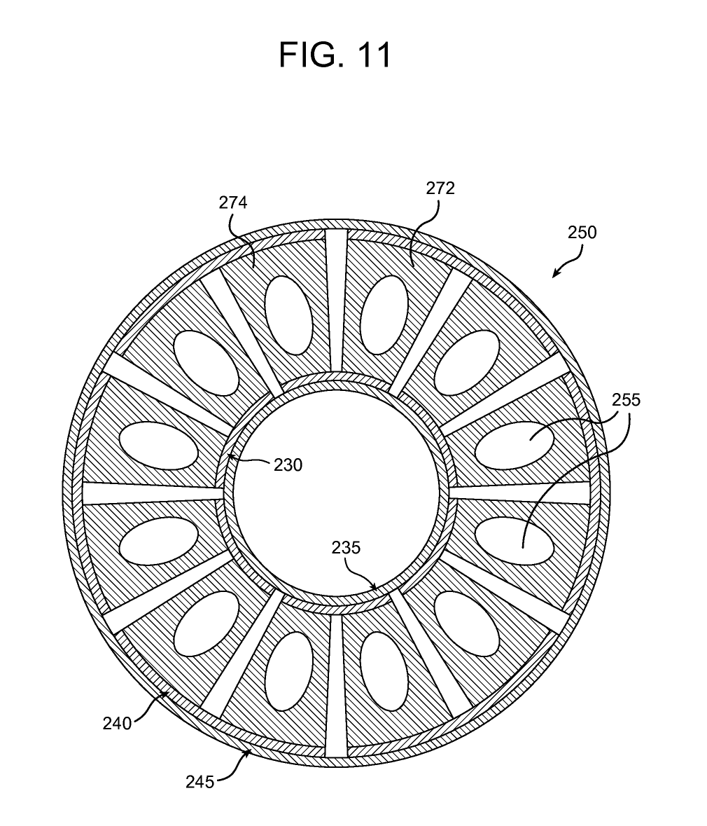

A further embodiment of a portion of a thermoelectric module having a cylindrical configuration is shown in FIG. 11. Module 250 comprises a plurality of thermoelectric elements each having a void 255 formed in an intermediate region of the element between contact surfaces with respective interconnects. The individual thermoelectric elements are shaped as prismatic wedges. The thermoelectric elements 272, 274 and interconnects 230, 240 are sandwiched between coaxial pipes 235, 245. A heat source and a heat sink can be provided within the inner core of the inner coaxial pipe and external to the outer coaxial pipe, respectively. In an alternate configuration, the location of the heat source and the heat sink can be interchanged.

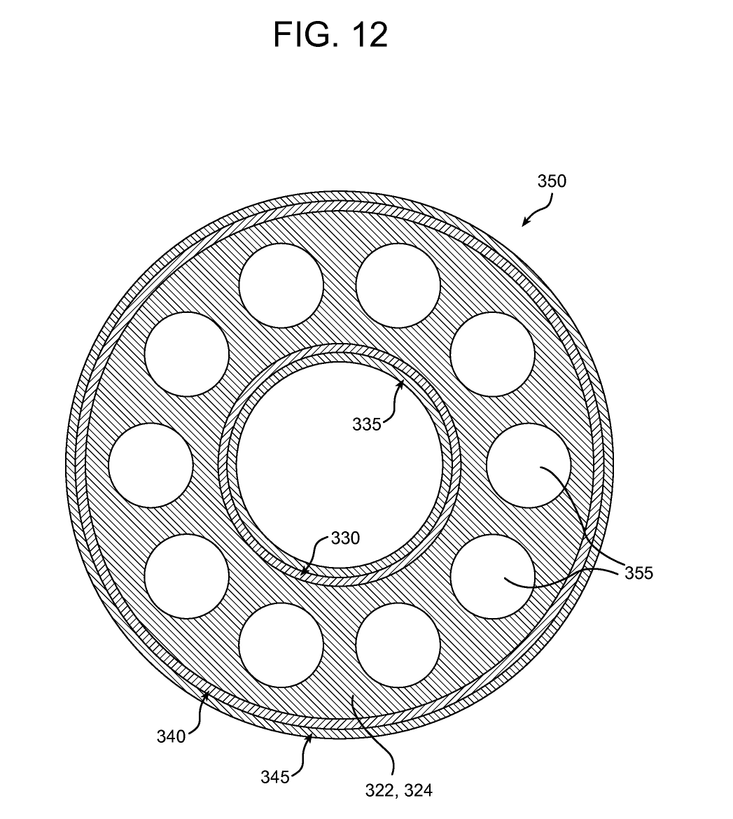

FIG. 12 shows a further example thermoelectric module 350 having a cylindrical design. The thermoelectric module 350 comprises disc-shaped (ring-shaped) n-type and p-type thermoelectric elements 322, 324 that are alternately stacked in an axial, cylindrical configuration. Each of the elements comprises a plurality of axially-oriented voids 355 that reduce the cross sectional area of the element between the respective contact surfaces of the element. The thermoelectric elements 322, 324 are electrically connected via circumferentially oriented electrical interconnects 330, 340. The thermoelectric elements and interconnects are sandwiched between coaxial pipes 335, 345. A heat source and a heat sink can be provided within the inner core of the inner coaxial pipe and external to the outer coaxial pipe, respectively. As with the previous design, the location of the heat source and the heat sink can be interchanged.

### EXAMPLES

Additional aspects of the disclosed thermoelectric elements are illustrated by the following examples.

Experimental measurements were performed on samples positioned within an thermally insulated chamber. The experimental module included four p/n pair configuration, where the dimensions (W×H×D) of the p-type legs and the n-type legs were 5×14×3 mm and 3×14×3 mm, respectively. A DC electric heater was used to raise and maintain a hot-side temperature, and a water cooled heat sink was used at the cold side of the module to maintain a desired temperature gradient. Copper blocks were used at the hot and cold sides to reduce local temperature variability. The hot and cold-side temperatures were measured close to alumina plates, which were positioned between the copper blocks and the respective heat source/heat sink. By varying the load, the open circuit voltage and I-V response were measured.

The experimental data validated a theoretical model, the fundamental assumptions of which are summarized in equations (1) and (2) below.

∇·\vec{j}=0 (1)

∇φ=−S∇T−\vec{j}/σ (2)

where \vec{j} is the current density (A/m²), φ is the electrical potential (V), S is Seebeck coefficient (V/K), T is temperature (K), and σ is the electrical conductivity (S/m).

Joule heating and Thomson effect were considered, such that

q=\vec{j}²/σ−μ\vec{j}·∇T (3)

where q is heat generated (W/m³), and μ is the Thomson coefficient, which can be written as

$$μ = T \frac{d S}{d T} \qquad ( 4 )$$

The Peltier effect at the intersection of the thermoelectric material and the respective electrode was also included.

Q|_{TE}_{_{—}}_{interface}=Π·I (5)

where Π is the Peltier coefficient (V), and I is current (A).

The heat transfer equation was solved with current conservation equations:

∇·(k∇T)+q=0 (6)

where k is the material thermal conductivity (W/m-K).

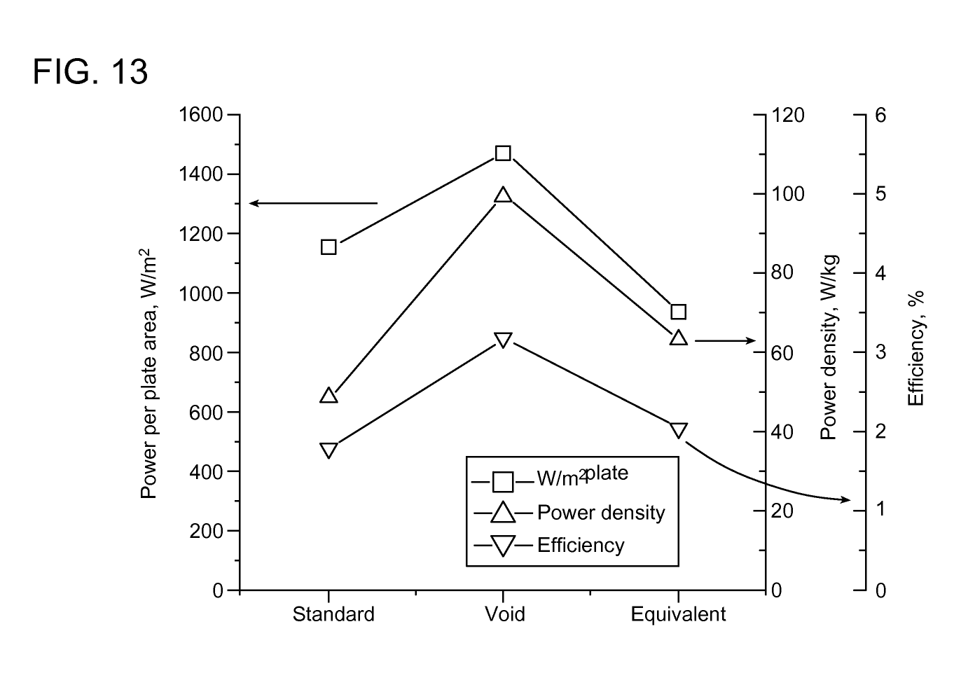

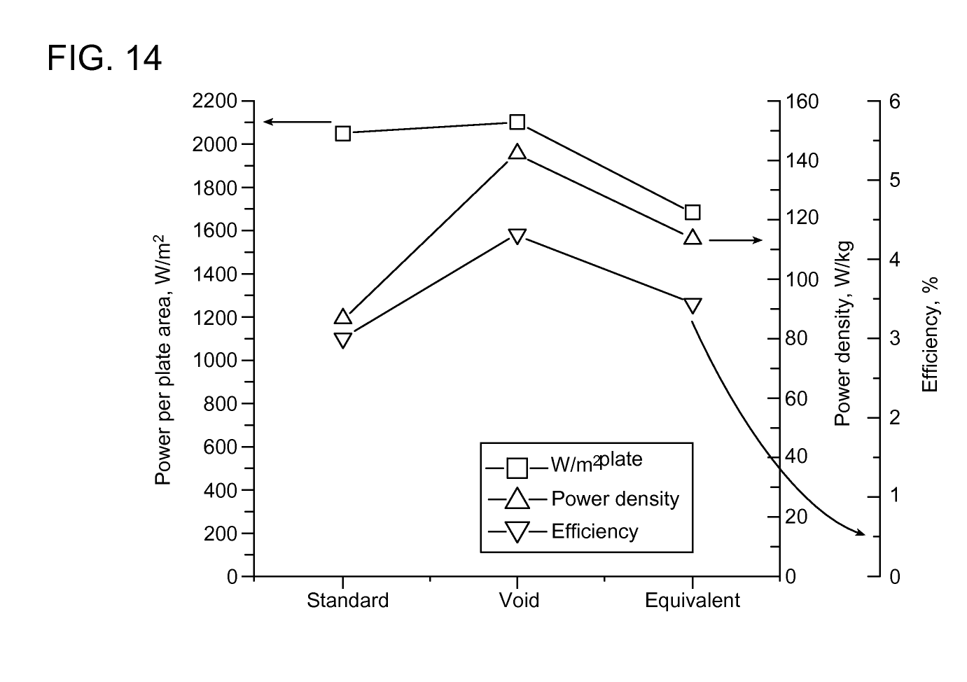

The calculated power per plate area (W/m²) power density (W/kg) and cell efficiency (%) for comparative and inventive thermoelectric element designs is shown in FIGS. 13 and 14. The data in FIGS. 13 and 14 assumes an electrical contact resistance of 4.6×10⁻⁸ ohm-m² and 6.0×10⁻⁹ ohm-m², respectively. The contact resistance is inversely related to contact area, and can have a negative impact on the total output power.

In FIGS. 13 and 14, “standard” refers to a traditional thermoelectric element geometry measuring 5×5×3 mm (W×H×D), and “void” refers to an inventive thermoelectric element geometry measuring 5×5×3 mm (W×H×D) and having a cylindrical 3×4×3 mm void cut through its center. “Equivalent” refers to a smaller cuboid which has the same total volume of TE material found in the “void” geometry. The dimensions of the equivalent design are 3.12×5×3 mm (W×H×D). FIGS. 13 and 14 show the theoretically calculated benefit of the disclosed design (“void”) where an intermediate region of a thermoelectric element has a smaller averaged cross-sectional area than the electrode contact areas at opposing ends of the element.

The data in FIGS. 13 and 14 clearly show that the inventive element comprising a void can provide higher power per hot surface area, higher output power per unit of thermoelectric material mass, and higher thermoelectric conversion efficiency than conventionally-shaped thermoelectric elements. A higher power per plate area can be desirable, particularly in applications where the available surface area to incorporate a thermoelectric generator is limited. The improvement in the foregoing properties can be explained by the higher thermal resistance of the disclosed design, which enables a higher temperature differential across the elements.

Compared with conventional devices, thermoelectric devices comprising the thermoelectric elements disclosed herein can achieve higher thermoelectric power conversion efficiency and higher electric power output per unit of material using a more compact design. In automotive applications, for example, the disclosed thermoelectric elements can reduce fuel consumption and CO₂ emissions via thermoelectric generator-based conversion of exhaust heat into electricity.

As used herein, the singular articles “a,” “an” and “the” include plural referents unless the context clearly dictates otherwise. Thus, for example, reference to “an oxide” includes examples having two or more such “oxides” unless the context clearly indicates otherwise.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It will be apparent to those skilled in the art that various modifications and variations can be made to the present invention without departing from the spirit and scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A thermoelectric element comprising:
a first end comprising a first contact surface and having a first cross-sectional area,
a second end comprising a second contact surface and having a second cross-sectional area, and
an intermediate region between the first end and the second end having an intermediate cross-sectional area where the intermediate cross-sectional area is less than both the first cross-sectional area and the second cross-sectional area.

2. A thermoelectric element according to claim 1, wherein the first cross-sectional area is substantially equal to the second cross-sectional area.

3. A thermoelectric element according to claim 1, wherein the first cross-sectional area lies in a first plane, the second cross-sectional area lies in a second plane, and the intermediate cross-sectional area lies in a third plane and the first, second and third planes are co-planar.

4. A thermoelectric element according to claim 1, wherein the thermoelectric element comprises a p-type thermoelectric material.

5. A thermoelectric element according to claim 1, wherein the thermoelectric element comprises an n-type thermoelectric material.

6. A thermoelectric element according to claim 1, wherein the thermoelectric element comprises a substantially homogeneous composition.

7. A thermoelectric element according to claim 1, wherein the thermoelectric element comprises a concave exterior surface.

8. A thermoelectric element according to claim 1, wherein the thermoelectric element comprises a voided region.

9. A thermoelectric element according to claim 1, wherein the intermediate cross-sectional area is from 10 to 99% of both the first cross-sectional area and the second cross-sectional area.

10. A thermoelectric element according to claim 1, wherein the thermoelectric element has an overall length of 1 to 20 mm.

11. A thermoelectric element according to claim 1, wherein the first contact surface has an areal dimension ranging from 1×1 mm² to 20×20 mm² and the second contact surface has an areal dimension ranging from 1×1 mm² to 20×20 mm².

12. A thermoelectric element according to claim 1, wherein the thermoelectric element has an “I” shaped cross-section.

13. A thermoelectric element according to claim 1, wherein the thermoelectric element has a “double-I” shaped cross-section.

14. A thermoelectric element according to claim 1, wherein the thermoelectric element has a wedge shape and includes a voided region.

15. A thermoelectric element according to claim 1, wherein the thermoelectric element has a disc shape and includes a plurality of voided regions.

16. A thermoelectric generator comprising the thermoelectric element according to claim 1.
